(19) United States
(12) Patent Application Publication
(10) Pub. No.: US 2011/0214727 A1
(43) Pub. Date: Sep. 8, 2011

(54) METHOD FOR MANUFACTURING A SOLAR CELL WITH A TWO-STAGE DOPING

(75) Inventors: Ainhoa Esturo-Breton, Konstanz (DE); Matthias Geiger, Konstanz (DE); Steffen Keller, Konstanz (DE); Reinhold Schlosser, Muenchen (DE); Catharine Voyer, Konstanz (DE); Johannes Maier, Konstanz (DE); Martin Breselge, Konstanz (DE); Adolf Muenzer, Unterschleissheim (DE); Tobias Friess, Konstanz (DE); Tino Kuehn, Radolfzell (DE)

(73) Assignee: CENTROTHERM PHOTOVOLTAICS AG, BLAUBEUREN (DE)

(21) Appl. No.: 13/128,304

(22) PCT Filed: Nov. 9, 2009
(86) PCT No.: PCT/IB2009/007380

§ 371 Date: May 27, 2011

(30) Foreign Application Priority Data
Nov. 7, 2008 (DE) 10 2008 056 456.7

(51) Int. Cl. H01L 31/06; H01L 31/18

(52) U.S. Cl. 136/255; 438/57; 257/E31.001

(57) ABSTRACT

A method for manufacturing a solar cell via a two-stage doping includes the steps of forming an oxide layer, which can be penetrated by a first dopant, on at least one part of the surface of a solar cell substrate, forming an opening in the oxide layer in at least one high-doping region by removing the oxide layer in this high-doping region and diffusing the first dopant into the at least one high-doping region of the solar cell substrate through the opening. The first dopant is diffused into the solar cell substrate through the oxide layer. The diffusing-in through the openings and through the oxide layer takes place at the same time in a common diffusion step and the solar cell substrate is diffused in the common diffusion step in an at least partially hydrophilic state.

The invention relates to a method for manufacturing a solar cell with a two-stage doping and also to a solar cell produced in accordance with this method.

In the production of solar cells, efforts are constantly being made to manufacture more efficient solar cells. Two-stage dopings, which can for example be in the form of a two-stage emitter doping or of a two-stage doping of a back surface field, have proven successful for this purpose. The two-stage doping of an emitter is conventionally referred to also as a selective emitter. Selective emitters are based on the idea of providing high-doping regions with a strong and deep doping below electrical contacts of the solar cell, whereas merely a weak and comparatively flat doping is provided in the surrounding regions of the contacts. In this way, it is possible to ensure in the high-doping regions a good electrical contact with sufficiently low electrical resistance between the strongly doped regions of the solar cell and a contact arranged thereabove and at the same time in the area surrounding the contacts or high-doping regions a reduced recombination of generated charge carriers owing to the weak doping prevailing there. Both have a positive effect on the efficiency of the solar cell produced.

Known methods for the manufacture of solar cells with a two-stage doping provide two separate diffusion steps for generating this two-stage doping. For example, a surface to be diffused of a solar cell substrate is first provided with a diffusion barrier which is impenetrable to the dopant used in the diffusion method applied and has openings in high-doping regions. Subsequently, in a first diffusion step, a strong doping is formed in these high-doping regions. Afterwards, the masking is removed and a planar, weak doping is carried out in a second diffusion step. This procedure is costly and is therefore used at most to a limited extent in the industrial production of solar cells.

The present invention is therefore based on the object of providing a method allowing a solar cell with a two-stage doping to be manufactured in a cost-effective manner.

This object is achieved by a method having the features of claim 1.

Furthermore, the invention is based on the object of providing a solar cell with a two-stage doping that can be produced in a cost-effective manner.

This object is achieved by a solar cell according to claim 21.

Advantageous developments form in each case the subject-matter of dependent claims.

The method according to the invention makes provision to form on at least one part of the surface of a solar cell substrate an oxide layer which can be penetrated by a first dopant and to remove the oxide layer in at least one high-doping region, so that an opening is formed there in the oxide layer. Furthermore, first dopant is diffused through the opening into the at least one high-doping region of the solar cell substrate and first dopant is diffused through the oxide layer into the solar cell substrate. The diffusing-in through the openings and the diffusing-in through the oxide layer take place in this case at the same time in a common diffusion step.

In this way, a two-stage doping is formed in a cost-effective manner in just one diffusion step. The doping is thus, as it were, a codiffused two-stage doping. In contrast to the formation of a two-stage doping in two separate diffusion steps, the present codiffusion places more stringent requirements on the process management during the diffusing-in of the first dopant. Whereas in methods according to the prior art a weak doping can easily be formed in that dopant is offered to a reduced degree during the associated diffusion, this is not possible in the present invention, as sufficient dopant must be provided in the high-doping regions. The diffusion parameters must therefore be adapted to one another in a suitable manner. In practice, a diffusion temperature in the range of from 750 to 950° C., a diffusion duration of from 5 to 60 minutes and a dopant concentration of from 1 to 10% of POCl₃ in oxygen have proven successful, for example, for the case of a phosphorus gas phase diffusion, i.e. a diffusion with deposition of dopant from a gas phase. In this way, it was possible to achieve layer resistances of about 50 Ω/sq in high-doping regions and layer resistances in the range of approx. 100 Ω/sq in surrounding regions.

In principle, the oxide layer can be opened in all known manners; in particular, etching media can be applied locally for etching the oxide layer or masking etching methods can be used in which the regions which are not to be opened are covered with an etching-resistant medium, known as a mask, before the oxide layer is overetched. In principle, photolithographic masking methods can also be used, although these increase the production costs considerably. Mechanical excavation methods, for example the sawing-in of ditches, are also conceivable. However, the oxide layer is preferably opened by means of laser ablation.

As the formation of the oxide layer is a high-temperature step which is known to be associated with the risk of an introduction of impurities into the solar cell substrate that can, in turn, have an adverse effect on the quality of the finished solar cell, the solar cell substrate is advantageously cleaned before the forming of the oxide layer. Cleaning methods which are suitable for this purpose are known and conventionally include an alkaline or acidic overetching of the solar cell substrate surface, the oxidation of metallic impurities by means of an acid and the hydrophobing of the solar cell substrate by means of a hydrofluoric acid-containing solution.

Furthermore, it has in practice proven successful, in particular when using solar cell substrates sawn from a block, to remove by wet chemistry the damage to the surface that is produced during the sawing. Saw damage etching of this type is therefore advantageously carried out before the forming of the oxide layer.

The first dopant used may be both p-doping and n-doping dopant. If a p-doped solar cell substrate forms the starting point for producing the solar cell, then phosphorus can for example be used as the first dopant for forming a selective emitter.

The arranging of electrical contacts, frequently referred to as the metallisation of the solar cell, in the high-doping regions or openings in the oxide layer can in principle take place in all manners known per se. In industrial production, paste printing methods, in particular screen printing methods, have become established for this purpose, so these are preferably used.

The common diffusion step is a high-temperature step entailing, again, the above-described risk of an introduction of impurities into the solar cell substrate. For this reason, solar cell substrates are conventionally cleaned before a diffusion step. As was previously stated in relation to the formation of the oxide layer, a hydrophobing of the surface of the solar cell substrate takes place in this case. This prevents impurities which have passed into the etching or rinsing media or are present there from entering the diffusion furnaces together with the solar cell substrates. The hydrophobing takes place in this case generally by an overetching of the solar cell substrates with a hydrofluoric acid-containing solution. Even dispensing on a one-off basis with such overetching with hydrofluoric acid is generally ruled out, as it is assumed that the impurities which are introduced into the diffusion tube as a result are at least partially enriched in the diffusion device, so that, even in the case of solar cell substrates which are introduced later into the diffusion device and were cleaned or hydrophobed beforehand using hydrofluoric acid, impurities are introduced into the solar cell substrate; this ultimately has an adverse effect on the efficiency of the solar cell substrates.

Against this background, a use of an oxide layer as a diffusion-inhibiting layer was disregarded in the past, as the oxide layer would be removed, during a hydrophobing of the solar cell substrates that was deemed to be indispensable, before the diffusion. However, it has surprisingly been found that an adequate cleaning effect can be achieved even without an overetching of the solar cell substrates with,a hydrofluoric acid-containing solution for the purpose of forming a hydrophobic surface, so that the production of outstandingly efficient solar cells is possible using the method according to the invention which, in contrast to a hydrophobing of the solar cell substrate before the diffusion, makes provision for the solar cell substrate to be diffused in an at least partially, preferably completely, hydrophilic state of the solar cell substrate.

A development of this method provides for the solar cell substrate to be etched, after the forming of the oxide layer and before the common diffusion step, in a solution containing an acid which oxidises metallic impurities, preferably hydrochloric acid, the solar cell substrate to be rinsed, after the etching, in deionised water and the solar cell substrate to be dried after the rinsing.

It has been found that it is possible to generate using this procedure, with low contamination of the solar cell substrates, good efficiency without removing the oxide layer and thus without hydrophobing. For the purpose of drying, use may in this case be made of basically all known drying methods. For example, a dried gas such as nitrogen can be used, preferably under the additional action of heat. The actual drying process can advantageously be preceded by a centrifuging or a blowing-down of the solar cell substrates. In this case, water is mechanically blown down or centrifuged down from the solar cell substrates as a consequence of the action of centrifugal forces or as a consequence of the mechanical action of a gas stream. This assists the subsequent drying and can speed up the drying.

A development of the invention provides for the solar cell substrate to be etched, after the forming of the oxide layer and before the common diffusion step, in an alkaline etching solution, preferably in an alkali hydroxide solution, at least one partial region of the oxide layer being exposed to the alkaline etching solution without protection. The at least one unprotected partial region of the oxide layer is in this case left at least in part on the solar cell substrate. This procedure has proven successful when the solar cell substrates are relatively highly contaminated. The alkali hydroxide solution used is in this case preferably sodium hydroxide or potassium hydroxide solutions. In so far as the etching in an alkaline etching solution is combined with the etching in an acid which oxidises metallic impurities, intermediate rinsing steps are obviously possible. In addition, the use of an alkaline etching solution has been found to be advantageous when the openings in the oxide layer are formed by laser ablation and the surface of the solar cell substrate is in this case damaged, as this damage can frequently be removed by the etching in the alkaline etching solution, i.e. for example in the case of silicon solar cell substrates.

A preferred variant embodiment of the invention provides for the at least one unprotected partial region of the oxide layer to be left at least in part on the solar cell substrate. Complete removal of the oxide layer during the etching in the alkaline solution is thus ruled out. This risk exists only in principle anyway, but is negligible in the case of the alkaline etching solutions Which are conventionally used for cleaning and the etching times which are conventional in this connection. However, both the etching rate of the alkaline etching solution and the etching time are in any case to be adapted in such a way that the oxide layer is not completely removed.

On use of a silicon substrate as the solar cell substrate and a silicon oxide layer as the diffusion-inhibiting oxide layer, a silicon oxide etching rate of the alkaline etching solution of less than 25 nm/min has proven successful in this connection.

In contrast to previously known cleaning methods, the above-described cleaning variants allow an advantageous diffusion of the solar cell substrate in an, at least partially, hydrophilic state.

The oxide layer which is to be formed in accordance with the method differs in its effect as a diffusion-inhibiting layer from thick oxide layers which act as a diffusion barrier and have in the past frequently been used in the production of solar cells. Thus, the homogeneity of the later weak doping is critically impaired by the homogeneity of the oxide layer and the variations in the thickness thereof. The oxide layer can be applied by means of a thermal oxidation, in particular by means of a wet thermal oxidation, by means of chemical vapour phase deposition or by means of action of UV light in an ozone atmosphere. As the homogeneity and variation in thickness of the oxide layer are critical, the process parameters for the oxidation must be carefully adapted. An oxidation temperature in the range of between 700 and 1,000° C. and an oxidation time of from 5 to 60 minutes have, for example, proven successful in the case of a wet thermal oxidation. In addition, the characteristics of the various depositing methods must be taken into account. Thus, for example, an oxide applied by means of chemical vapour deposition can have a different density, and thus a different diffusion-inhibiting effect, to that of a thermal oxide. This can advantageously be utilised if comparatively thin oxide layers are required. Chemical vapour deposited oxide layers (“CVD layers”) can be used in this case. Such layers may be formed at a lower density than, for example, thermal oxide layers. Low-density CVD layers can therefore be applied at a greater thickness than oxide layers having a comparable diffusion-inhibiting effect that are produced in a different manner. However, thicker layers are technologically often easier to handle. This applies in particular to the oxide layers having a thickness of between 2 nm and 70 nm that are preferably used in the methods according to the invention. The CVD layers can in this case be generated under atmospheric pressure (APCVD), under low pressure (LPCVD) or else in a plasma-enhanced manner (PECVD). In addition, CVD layers can be manufactured cost-effectively.

An advantageous variant embodiment of the invention provides for the solar cell substrate to be provided, before the forming of the oxide layer, at least on a part of the surface of the solar cell substrate with a microstructure, the structures of which have substantially a structure diameter of less than 100 μm, preferably of less than 50 μm and particularly preferably of less than 15 μm. At least one part of the oxide layer is subsequently formed on this microstructure. Preferably, the microstructure is formed from a wet-chemically generated texture. Alternatively, the microstructure could be generated, for example, by means of plasma etching. The term “a texture” refers in this case to a surface structuring of the solar cell substrate that is known to be used for reducing the reflection of incident light at the surface of the solar cell substrate. In principle, a texture of this type can be generated by means of mechanical structuring, for example by means of sawing, or else by wet chemistry. In principle, alkaline or acidic texture etching solutions can be used for generating a texture by wet chemistry. A high degree of isotropy of the texture can be achieved, in particular, using acidic texture etching solutions. It has been found that the formation of a microstructure is important above all in multicrystalline solar cell substrates, as oxide layers grow at differing speeds on differently oriented grains. This greatly impedes the formation of homogeneous oxide layers on multicrystalline materials. If, on the other hand, the multicrystalline solar cell substrates were provided with a microstructure of the described type, then the oxide growth is uniform, at least on a macroscopic scale, and a homogenous oxide layer can be applied with low variations in thickness.

A development of the invention provides for, before the forming of the oxide layer, a layer containing a second dopant to be formed on the back of the solar cell substrate and second dopant to be diffused from this layer into the solar cell substrate. In this way, a back surface field can be formed. Generally, the second dopant is of a different type from the first dopant. If, for example, a p-doped solar cell substrate is present and if the first dopant is an n-doped dopant, for example phosphorus, then the second dopant is a p-doped dopant, for example boron. Preferably, the layer containing a second dopant is formed only on the back and thus not on the front of the solar cell substrate. As this is conveniently possible by means of a CV deposition, methods of this type are preferably used, in particular APCVD methods. However, alternatively, the back could for example be lined with a dopant-containing solution, for example by spinning-on this solution.

In p-doped solar cell substrates, the diffusing-in of boron, corresponding to the formation of a boron-doped layer having a layer resistance of about 10 Ω/sq, has proven successful for forming solid back surface fields. The boron-doped layer is driven in deep, preferably deeper than about 1 μm. An overcompensation of the back surface field by the subsequent diffusion step for diffusing-in the first dopant is not to be expected in this case, as the phosphorus is driven in less deep, preferably less deep than 0.5 μm; this is not sufficient to overcompensate the solid, deeply driven-in boron doping.

In principle, however, boron dopings having a higher layer resistance, for example a layer resistance of about 60 Ω/sq, can also be formed on the back of the solar cell substrate. However, it should then expediently be ensured that, in the subsequent diffusion step for introducing the first dopant, the back boron doping is at least not compensated or overcompensated beyond the entire depth of the doping profile.

While the solid doping of the back with a second dopant, in particular with boron, allows a satisfactory passivation for reducing the recombination of the charge carriers on the back of the solar cell, an additional passivation is required in the case of a moderately doped back surface field, for example a back surface field having the above-described layer resistance of about 60 Ω/sq. However, in return, the additional passivation allows an optically transparent back which, in turn, allows optical measures, such as for example an optical mirroring, to be provided for reducing the losses in coupled-in light. Furthermore, what is known as light-trapping is possible. The mirroring can for example take place by means of a metal layer such as aluminium. Alternatively, dielectric layers can also be provided for mirroring the back.

Glass layers formed during the forming of the layer containing second dopant or during the diffusing-in of the second dopant from this layer can in principle still be maintained, at corresponding purities of the boundary layers and low surface state densities, for passivating the back and as a reflection layer. This applies in particular when solid back surface fields have been formed (see above). The boundary layer between the layer containing the second dopant, for example the boron/silicon oxide layer, can if appropriate be subsequently improved by tempering. This can take place, for example, in forming gas. However, preferably, the aforementioned glass layers formed are removed. This take place preferably by wet chemistry.

A moderate boron back surface field can be passivated, for example, by means of a phosphorus doping. In order to further improve this passivation and also to form an optical back mirror, an advantageous variant embodiment of the invention therefore provides for, after a diffusion of a second dopant into the solar cell substrate, during the diffusion step, first dopant to be diffused into the back of the solar cell substrate and, after the diffusion step, a silicon nitride layer to be applied to the front and the back of the solar cell substrate. This silicon nitride layer is in this case preferably chemical vapour deposited, in particular at low pressure (LPCVD) or at atmospheric pressure (APCVD). In so far as an oxide layer is present on the back before the diffusion step, the oxide layer is preferably removed before the diffusion step.

A preferred variant embodiment of the invention provides for the oxide layer to be formed on the front and on the back of the solar cell substrate and the oxide layer formed on the back of the solar cell substrate to be provided with a protective layer which is resistant to an oxide etching medium. In this way, a layer which is made of second dopant and was diffused-in beforehand on the back can, for example, be passivated by means of an oxide layer. In this case, as also in other cases in which the oxide layer remains on the solar cell substrate, the oxide layer should therefore advantageously be applied in passivating quality. However, even if no second dopant is diffused-in on the back, the back of the solar cell substrate can be passivated by means of the applied and protected layer. In both cases, the protective layer is advantageously selected in such a way that it, on the one hand, strengthens the passivation effect where possible and, on the other hand, improves the optical properties of the back, for example by increasing the back reflection. In an advantageous variant embodiment, the protective layer applied is therefore a silicon nitride layer. In addition, layers made of silicon carbide and aluminium oxide can advantageously be used as the protective layer. As an alternative to protective layers, use may also be made of covering sacrificial layers which are made, for example, of silicon oxide and ensure that the silicon oxide layer, which is applied first, remains on the solar cell substrate.

The protective layer is applied preferably by means of a CVD method which can conveniently be used to carry out a coating on one side. In order to achieve a particularly good protective effect, a PECVD silicon nitride layer is preferably applied, wherein APCVD and LPCVD coatings can in principle also be used. In addition, it is possible to form the protective layer by sputtering.

In so far as a variant embodiment of the method according to the invention provides an optional texture etching, this can take place in principle on one side or on both sides, i.e. on the front or on the front and back. In so far as a texture is provided on both sides, a back polish etching may afterwards be advantageous in order to achieve, if appropriate in conjunction with dielectric coatings applied to the back, a passivation which is as extensive as possible and maximum back reflection.

A particularly advantageous development of the invention provides, in addition to the forming of a protective layer on the back oxide layer, for, on the back of the solar cell substrate before the diffusion step, local openings to be introduced into the oxide layer and also the protective layer and the oxide layer on the front to be removed by means of an oxide etching medium after the diffusion step. The local openings are introduced, in an advantageous variant embodiment, before the diffusion step. Furthermore, they are introduced into the oxide layer and the protective layer preferably by means of laser ablation. The oxide layer on the front is removed preferably by means of a hydrofluoric acid-containing solution. As the back oxide layer is provided with the protective layer, it is preserved, together with the protective layer, even after the diffusion step. Subsequently, electrical contacts can be arranged in the local openings on the back. This takes place preferably by means of screen printing technology. This provides a local contacting of the back of the solar cell that is particularly advantageous with regard to reducing the back charge carrier recombination.

The diffusion after the local opening of the back oxide layer can, in addition, cause an advantageous gettering effect, for example if the first dopant used is phosphorus. In this case, a gettering of impurities can be implemented as a result of the diffusing-in of the phosphorus through the local openings of the back in these points.

Preferably, the local openings in the oxide layer and protective layer are formed in a point-by-point manner on the back and distributed uniformly over the back of the solar cell substrate.

Preferably a metal-containing screen printing paste having a low glass frit content, particularly preferably an aluminium-containing paste, is used for introducing the electrical contacts into the local openings of the back. As a result of the low glass frit content, damage to the oxide layer and also the protective layer is substantially avoided. In this way, point contacts can be formed in the local openings. In order to be able to contact the point contacts reliably and with sufficiently low electrical resistance, they are advantageously overprinted with a further paste containing, for example, silver and aluminium. The front is contacted in a manner known per se, in particular by means of screen printing, and advantageously after applying an antireflection coating to the front. This antireflection coating can be formed, for example, of a silicon nitride layer, in particular a PECVD silicon nitride layer. The contacts of the front and back are then preferably jointly fired; this may in some cases be referred to as cofiring.

In so far as the electrical contacts are, as proposed, formed in the local openings by means of an aluminium-containing paste, a local back surface field is formed, at the same time as the cofiring, in the regions of the local openings on the back. However, in principle, the aluminium can also be introduced into the local openings in a manner other than by means of a screen printing paste, for example by spray printing or vapour deposition.

In the case of the formation, which took place in the above-described manner, of local rear contacts by forming local openings in the back oxide layer and also the protective layer, edge separating, which reduces the active area of the solar cell, may advantageously be dispensed with.

Solar cells can advantageously be produced by means of the method according to the invention. In particular, solar cells with a selective emitter, but also buried-contact solar cells, can be manufactured cost-effectively. However, with regard to buried-contact solar cells, it should be borne in mind that in this case not only is an opening formed in the oxide layer in high-doping regions, but rather a few tens of micrometres of the solar cell substrate are at the same time also excavated in order to form the ditches which are typical of this type of cell. However, with regard to the contacting of buried-contact solar cells, it should be borne in mind that an antireflection coating, generally silicon nitride, which may be applied later, is to be contacted-through. This can take place by screen printing or by applying an aerosol seed layer in the ditches with subsequent plating.

An advantageous variant embodiment of a solar cell according to the invention has a two-stage doping which is arranged on a front and formed using a first dopant. In addition, this variant embodiment has a doped layer which is formed on a back of the solar cell using a second dopant, the second dopant being of a type opposed to the first dopant. Furthermore, first dopant has diffused into a partial region of the doped layer that faces the back surface of the solar cell, the first dopant overcompensating the second dopant in this partial region. Furthermore, a silicon nitride cover layer is provided at least on the front and the back of the solar cell.

Advantageously, the first dopant is formed by phosphorus, the second dopant by boron. The partial overcompensation of the doped layer on the back of the cell by the doped-in phosphorus causes a better passivation of the back than the boron-doped layer alone. The passivation effect is further intensified by the back silicon nitride layer which additionally improves the optical properties of the back of the solar cell and thus the back reflection. In a preferred variant embodiment, the solar cell is in this case in the form of a silicon solar cell.

The silicon nitride layer can be deposited by means of PECVD or LPCVD. A doping concentration corresponding to a layer resistance of 45 Ω/sq has proven successful with regard to the doping with the first dopant; a doping concentration corresponding to a layer resistance of about 60 Ω/sq has proven successful for the doped layer formed by means of the second dopant.

The invention will be described hereinafter in greater detail with reference to figures. In the figures, equivalent elements are provided with the same reference numerals, in so far as this is expedient. In the drawings:

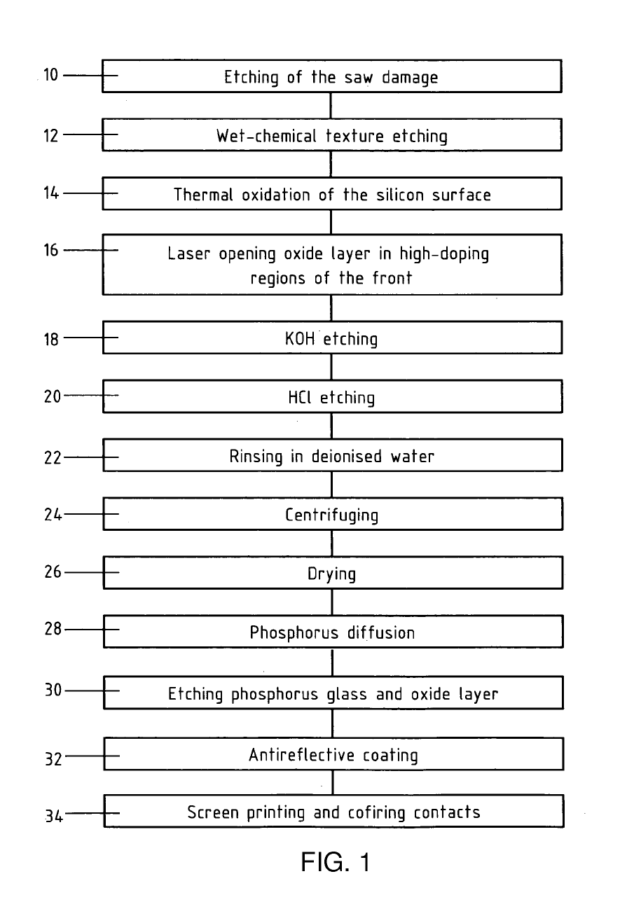

FIG. 1 is a schematic representation of a first exemplary embodiment of a method according to the invention;

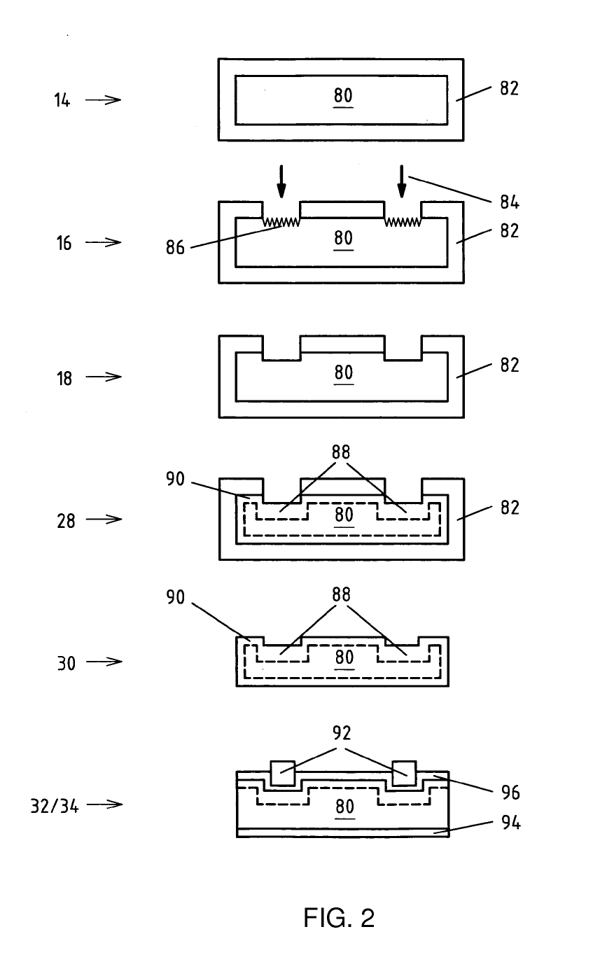

FIG. 2 is a schematic illustration of individual process steps of the exemplary embodiment of FIG. 1;

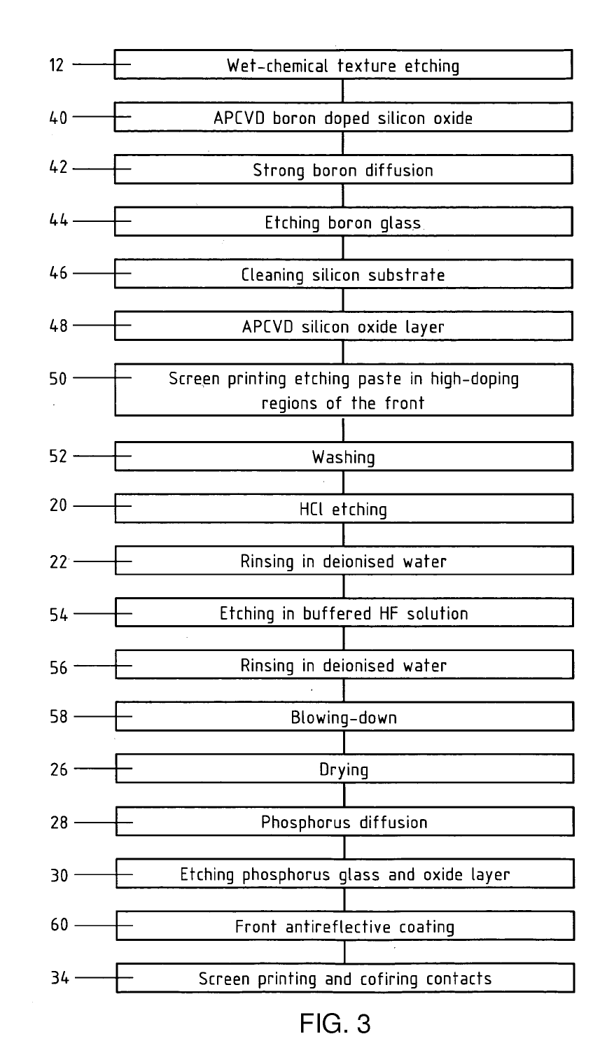

FIG. 3 is a schematic representation of a further exemplary embodiment of a method according to the invention in which a layer containing boron as the second dopant is formed on the back of the solar cell substrate;

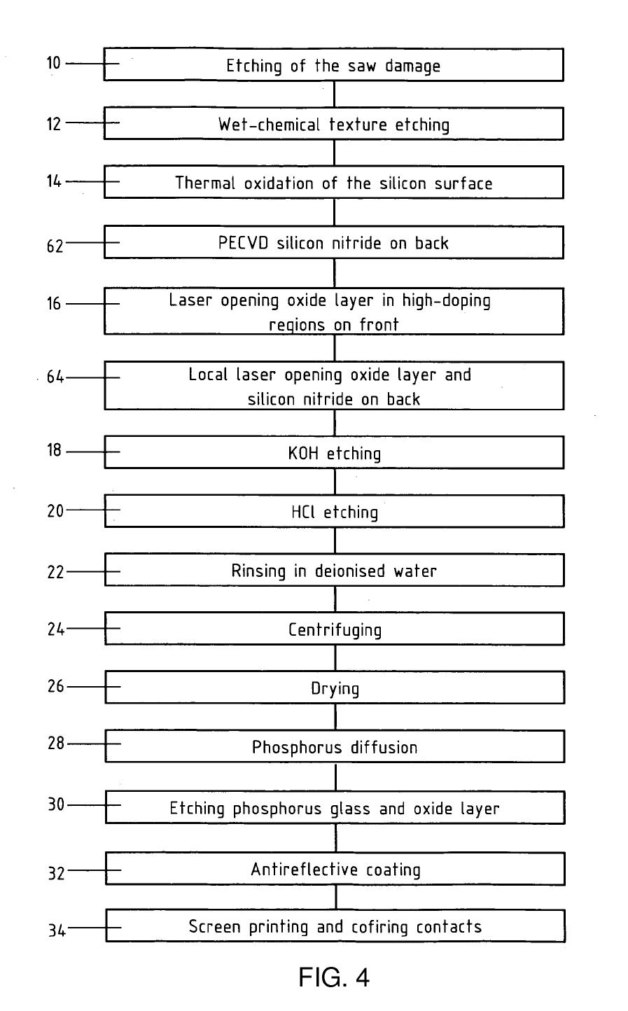

FIG. 4 is a schematic representation of a further exemplary embodiment of the method according to the invention in which local rear contacts are formed with the local BSF;

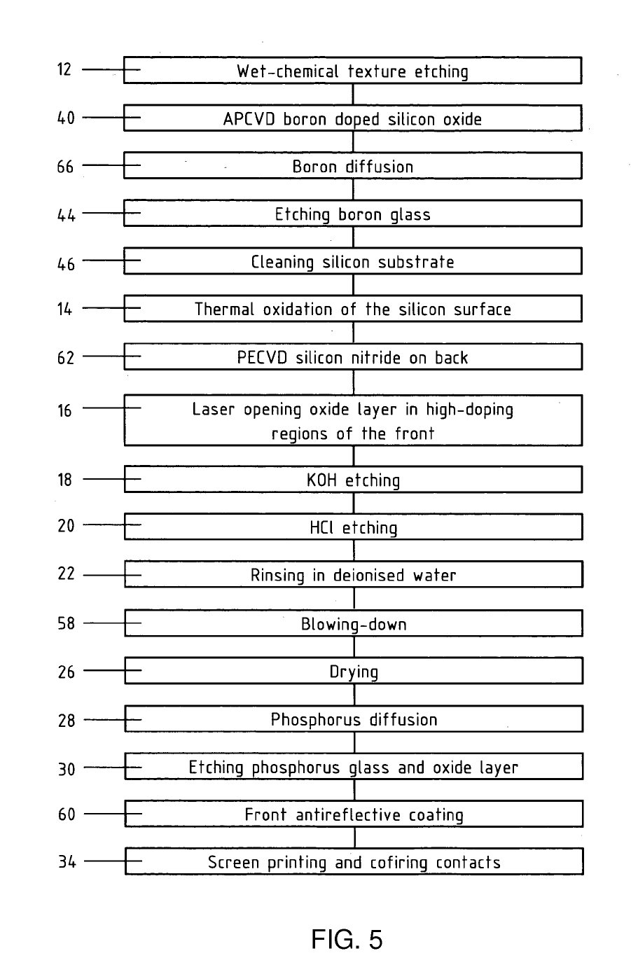

FIG. 5 is a schematic representation of an exemplary embodiment of a method according to the invention in which the diffusion-inhibiting oxide layer is used for passivating a back boron back surface field;

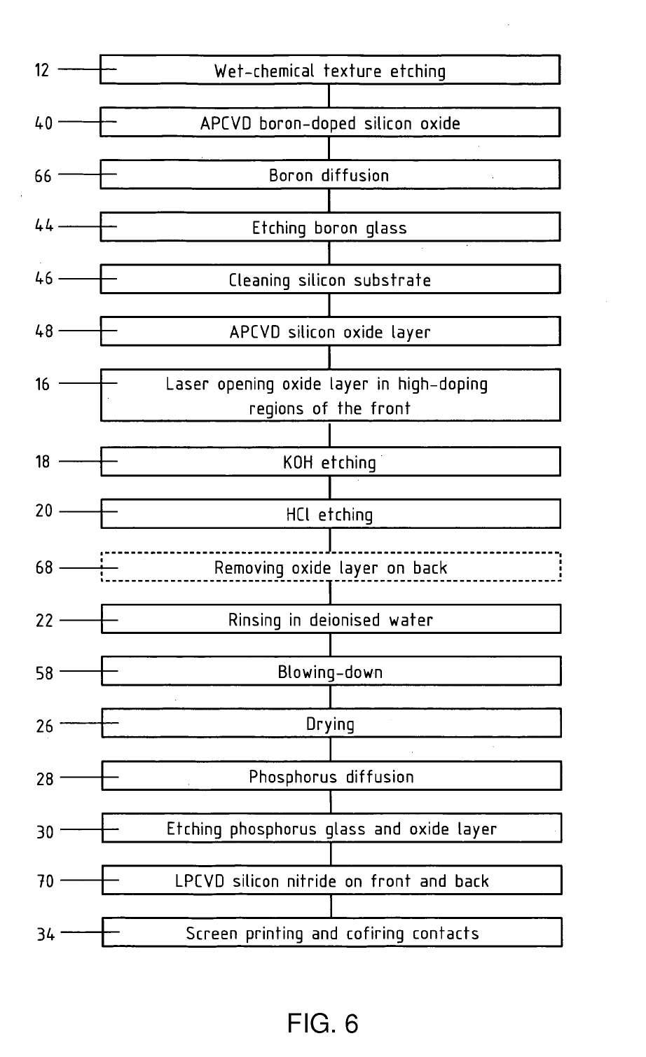

FIG. 6 is a schematic representation of a further exemplary embodiment for a method according to the invention with an optional step for removing the oxide layer on the back of the solar cell substrate; and

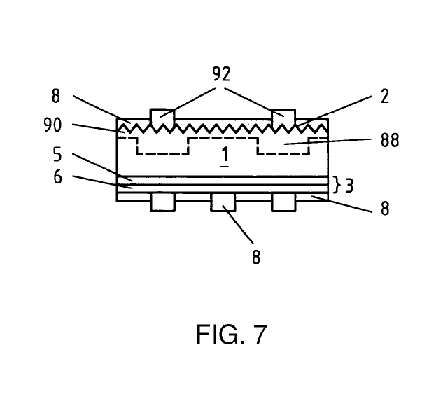

FIG. 7 is a schematic representation of an exemplary embodiment of a solar cell according to the invention.

FIG. 1 is a schematic representation of a first exemplary embodiment of the method according to the invention. This exemplary embodiment provides firstly the optional step of saw damage etching 10, followed by the forming 12 of a texture by wet-chemical texture etching. This is followed by the forming 14 of an oxide layer; in the present exemplary embodiment, this takes place by thermal oxidation of the silicon surface of the silicon substrate which is used in the present case. The thermal oxidation 14 includes, in this exemplary embodiment as in the following exemplary embodiments, in all cases a prior cleaning of the solar cell substrate in order to reduce the risk of an introduction of impurities during the high-temperature step. The representations of FIG. 2 illustrate the effects of selected process steps of the process sequence from FIG. 1 on the silicon solar cell substrate 80. As may be seen from FIG. 2, the forming 14 of the oxide layer leads to an extensive layer made of silicon oxide 82.

It should be noted that, in the representations of FIG. 2, the texture, which is formed 12 by means of wet-chemical etching, has not been reproduced for the sake of clarity.

Furthermore, the oxide layer is opened 16 in high-doping regions of the front by means of laser radiation 84. FIG. 2 illustrates laser damage 86 which may be produced, depending on the laser used and parameters selected.

The laser opening is followed by a cleaning sequence in which the silicon oxide layer 82, which is formed during the thermal oxidation 14, is exposed to the etching media without protection, but not yet completely removed. This cleaning sequence is formed from an etching 18 in potassium hydroxide solution followed by an etching 20 in hydrochloric acid and a subsequent rinsing 22 in deionised water. As the use of hydrofluoric acid is dispensed with altogether, the silicon solar cell substrates 80 are in a hydrophilic state. For this reason, drying 26 thereof is provided, which is preceded by a centrifuging 24 of the solar cell substrates 80 in order to speed up the drying process. As may be seen from the representation of FIG. 2, this cleaning sequence also affords the advantage that any laser damage 86, which can entail an increased recombination of generated charge carriers, is removed during the etching 18 in potassium hydroxide solution (KOH solution).

Afterwards, there follows a diffusion step 28 which in the present exemplary embodiment is in the form of a phosphorus diffusion step, the silicon solar cell substrate being assumed to be p-doped. However, in principle, a boron diffusion can also take place. The present phosphorus diffusion 28 can be implemented by a deposition of a dopant from a gas phase, for example with a POCl₃ diffusion.

The phosphorus diffusion is carried out as strong phosphorus diffusion, i.e. a layer resistance of from typically about 10 to 50 Ω/sq is set in unprotected regions of the solar cell substrate 80. This also occurs in the high-doping regions 88 which are strongly doped as a consequence of this strong diffusion 28. In the remaining regions, on the other hand, the surface of the solar cell substrate 80 is protected by the silicon oxide layer, so that weakly doped regions 90 are present there. For example, layer resistances of approx. 100 Ω/sq are striven for here.

Following the phosphorus diffusion 28, the phosphorus glass, which was produced during the phosphorus diffusion 28, and also the remnants of the oxide layer 82 are removed. Preferably, this takes place in a common, wet-chemical method step.

Subsequently, an antireflection coating 96, for example in the form of a silicon nitride coating, is attached 32 in a manner known per se and also front contacts 92 and back contacts 94 are applied 34 by means of screen printing in a manner known per se. These contacts 92, 94 are afterwards cofired 34. The back contact used is preferably an aluminium-containing paste, so that the back emitter is overcompensated and a back surface field 94 is formed as a consequence of the firing.

FIG. 3 is a schematic representation of a further exemplary embodiment of the method according to the invention. As well as dispensing with an initial saw damage etching (although this can be integrated without difficulty), this exemplary embodiment makes provision for the formation 40 of a boron-doped silicon oxide on the back of the silicon solar cell substrate. This takes place by means of an APCV deposition. A strong boron diffusion is carried out 42 afterwards. The term “a strong boron diffusion” refers to a boron diffusion leading to a layer resistance in the range of about 10 Ω/sq on the silicon solar cell substrate which is used. A boron back surface field, or boron BSF for short, is formed in this way. The back boron glass could, in the case of the strong boron diffusion 42 provided here, in principle remain as a passivation layer on the solar cell substrate. Nevertheless, in the represented exemplary embodiment, the back boron glass is removed 44, by way of example, by etching.

Afterwards, the silicon substrate is cleaned 46. As no masking oxide was previously applied, this cleaning can provide, in particular, a hydrophobing of the surface of the solar cell substrate. Subsequently, a silicon oxide layer is formed 48 by means of APCVD, at least on the front of the solar cell substrate. This oxide layer is afterwards opened 50, again in high-doping regions. For this purpose, an etching paste is imprinted locally, for example by means of screen printing, onto the high-doping regions. After a sufficient reaction time, the etching paste has opened the oxide layer and can be removed in a subsequent washing step 52. An etching then takes place in hydrochloric acid 20 with subsequent rinsing 22 in deionised water. As screen printing pastes, and thus also the etching paste used, contain a large number of components, a further cleaning step of the etching 54 in buffered hydrofluoric acid (HF) solution is provided for the sake of safety, followed by a further rinsing step 56. In the case of high contamination, an etching in an alkaline etching solution could additionally be provided. If there is hardly any risk of impurities, it is possible to consider dispensing with the etching 54 in buffered HF.

The rinsing 52 is followed, again, by a drying step 26 which is preceded, in this exemplary embodiment, by a blowing-down 58 of the solar cell substrate in order to speed up the drying. After the drying, the phosphorus diffusion 28 is, again, carried out and afterwards the phosphorus glass and the remnants of the oxide layer are removed 30. Furthermore, a front applying 60 of an antireflection coating is provided in the present case. In so far as the antireflection coating used has, in addition, passivating properties or is able to improve the back reflection, deposition thereof on the back may also be considered; for example in the case of silicon nitride.

FIG. 4 illustrates a schematic representation of a further exemplary embodiment of the method according to the invention. This exemplary embodiment differs from the exemplary embodiment of FIG. 2 in that, after the forming 14 of the oxide layer on the back of the silicon solar cell substrate, a PECVD silicon nitride layer is formed 62 as a protective layer on the oxide layer. As a consequence of this protective layer, the back oxide layer is preserved even during the etching 30 of the phosphorus glass and the oxide layer. Preferably, the protective layer is therefore formed in a quality allowing a good passivation of the back. For this reason, a thermal oxidation 14 is preferable over a CV deposition. However, in principle, silicon oxide CV deposition would be conceivable. The protective layer itself can assume an additionally positive influence if a suitable material is selected. Thus, for example, an optically active silicon nitride layer allows the reflection behaviour on the back of the solar cell to be positively influenced.

A further difference to the method from FIG. 2 consists in the fact that both the oxide layer and the protective layer arranged thereon are locally opened 64, in the present case by means of laser ablation, on the back. These local openings allow, as described above, the formation of local rear contacts in the otherwise passivated back. As the local opening 64 of the back takes place before the phosphorus diffusion, a local P-gettering is also possible in the regions of these local back openings. In so far as this gettering effect is dispensed with, the back oxide layer as well as the protective layer can also be locally opened at any desired later moment, in particular immediately before the applying 34 of the contacts.

The subsequent method steps have already been discussed in relation to FIG. 2. Nevertheless, with regard to the screen printing of the contacts, it should be borne in mind that the back contacts are to be orientated onto the local back openings. Advantageously, as described above, an aluminium-containing paste having a low class frit content is firstly printed into the local back openings, before the back openings are overprinted with contact faces, the back openings preferably being formed from a silver and/or aluminium-containing paste. This produces, in addition to a local aluminium BSF in the local back openings, a back which is convenient to contact.

The exemplary embodiment of FIG. 5 differs from that of FIG. 3 in the first place in that strong boron diffusion is not provided. In the case of a moderate boron diffusion 66 of the present type, the layer resistance of the boron-doped layer is in the range of about 60 Ω/sq. A boron diffusion 66 of this type can be carried out at lower temperatures than a strong boron diffusion. This is advantageous in particular in the case of multicrystalline solar cell substrates provided with a large number of crystal defects. Nevertheless, such a moderate boron doping displays only inadequate passivation properties. Expediently, an additional passivation of the back should therefore be provided. In the present exemplary embodiment, this takes place using an oxide layer, more precisely a silicon oxide layer. Thus, in a departure from the method of FIG. 3, the oxide layer is formed 14 by means of a thermal oxidation. The resulting oxide layer is additionally provided 62 on the back with a protective layer. For this purpose, a PECVD silicon nitride layer is deposited 62 on the back.

In all other respects, the method of FIG. 5 does not differ fundamentally from that of FIG. 3. After all, although according to FIG. 5 the oxide layer is opened 16 by means of laser ablation on the front, this could in principle also take place using a locally imprinted etching paste with subsequent washing of the silicon solar cell substrate. The dispensing with the additional cleaning step of the etching 54 in buffered HF with subsequent rinsing 56 is not a fundamental difference either. An additional cleaning step of this type can be integrated into the method according to FIG. 5 if required.

This therefore results in a boron back surface field which is passivated by means of a composite structure made up of a silicon oxide layer and the silicon nitride layer arranged thereon. At the same time, these dielectrics influence the optical back properties and can be suitably adapted with regard to their thickness.

The exemplary embodiment of FIG. 6 illustrates a different route for passivating a moderate boron back surface field: In a departure from the variant embodiment of FIG. 5, the oxide layer is formed 48 here by means of APCV deposition of a silicon oxide layer on the silicon solar cell substrate. A protective layer for an oxide layer applied to the back is not provided. Instead, the applied oxide layer is opened 16 straight away on the front in high-doping regions. Due to considerations of analogy, a laser ablation method is used for this purpose both in FIG. 6 and in FIG. 5. However, in principle, the oxide layer can also be opened in a different manner, for example by means of locally applied etching paste. In all other respects, with the etching 18, 20 in KOH and HCl, the rinsing 22, the blowing-down 58, the drying 26, the phosphorus diffusion 28 and the etching 30 of the phosphorus glass and oxide layer, the same method steps are provided as in FIG. 5.

However, one difference is the optional step of removing 68 the oxide layer on the back of the solar cell substrate. This is carried out, in so far as an oxide layer was formed on the back, for example in that the APCV deposition 48 was carried out on both sides or if a thermal oxidation would have been used. For this reason, it is advantageous to use a one-sided CVD method to form the oxide layer, as the additional step of removing 68 the back oxide layer may then be dispensed with.

The removal 68 of the oxide layer, in so far as it is required, has the consequence that first dopant, i.e. in the present case phosphorus, is diffused 28 into the back of the cell during the phosphorus diffusion 28. As a passivation of a phosphorus-doped layer is easier to implement than the passivation of a moderately boron-doped layer, this simplifies the passivation problems. It is therefore now possible to ensure a passivation, for example by subsequently applying 70 an LPCVD silicon nitride layer to the back, thus allowing the surface recombination speed to be reduced at the back of the solar cell substrate. In the method according to FIG. 5, it should be noted that the boron doping is driven in sufficiently deep, so that the subsequent phosphorus doping, which has been driven in flat, has no fundamental influence on the electrical properties, in particular the back surface field, of the boron doping. However, an overcompensation of the boron doping by means of the diffused-in 28 phosphorus is to be provided close to the back surface of the solar cell substrate.

Advantageously, the LPCVD silicon nitride is applied 70 to the front and back at the same time. In this way, its passivating and reflection-reducing properties can also be utilised on the front. The contacting takes place, again, by means of screen printing 34 of the contacts and cofiring 34.

FIG. 7 is a schematic representation of an exemplary embodiment of a solar cell 1 according to the invention. The solar cell is manufactured in accordance with the method of FIG. 6. Accordingly, it has a texture 2 and also a two-stage emitter formed by strong high-doping regions 88 and weakly doped regions 90. The emitter 88, 90 is in the present case formed using phosphorus as the first dopant. A doped layer 3, which is formed using a second dopant, preferably boron, is provided on the back. First dopant, in this case phosphorus, is diffused on the back of the solar cell 1 in a partial region 6 facing the back surface of the solar cell 1, the first dopant overcompensating the original boron doping in this partial region 6. The non-compensated partial region 5 of the boron-doped layer causes the desired boron BSF. On the front of the solar cell 1, the front contacts 92 are arranged in the high-doping regions 88. Both the front contacts and the rear contacts are fired-through by an LPCVD silicon nitride layer 8.

In the foregoing exemplary embodiments, the invention has been described based on a silicon solar cell substrate. Obviously, other semiconductor materials can also be used. Furthermore, all thermal oxidations can also be in the form of wet thermal oxidations. As all the exemplary embodiments of the method according to the invention make provision for the formation of a texture, they can advantageously be used to manufacture multicrystalline solar cells. In addition, the methods according to the invention can obviously also be used in conjunction with n-doped solar cell substrates. Moreover, alkaline etching solutions other than KOH, in particular a sodium hydroxide solution, can also be used in all the exemplary embodiments.

A texture formed merely on the front is advantageous in all the exemplary embodiments. In the case of a back texture, this texture can be etched back by wet chemistry.

Obviously, the formation of a boron-doped layer does not necessarily require the forming of a boron-doped CVD silicon oxide layer. Instead, boron-containing media can in principle be applied to the back and diffused-in in any manner.

### LIST OF REFERENCE NUMERALS

1 Solar cell

2 Texture

3 Boron-doped layer

5 Non-compensated partial region

6 Overcompensated partial region

7 Rear contact

8 LPCVD silicon nitride

10 Saw damage etching

12 Forming texture

14 Forming oxide layer

16 Laser opening oxide layer

18 Etching in potassium hydroxide solution

20 Etching in hydrochloric acid

22 Rinsing

24 Centrifuging

26 Drying

28 Diffusion step

30 Removing phosphorus glass and oxide layer

32 Applying antireflection coating

34 Applying/cofiring contacts

40 Forming boron-doped silicon oxide

42 Strong boron diffusion

44 Removing boron glass

46 Cleaning

48 Forming oxide layer

50 Screen printing etching paste

52 Washing solar cell substrate

54 Etching in buffered hydrofluoric acid

56 Rinsing

58 Blowing-down

60 Applying antireflection coating on front

62 Forming protective layer

64 Local laser opening of the oxide layer on back

66 Boron diffusion

68 Removing oxide layer on back

70 Applying LPCVD silicon nitride

80 Silicon solar cell substrate

82 Silicon oxide

84 Laser radiation

86 Laser damage

88 Strongly doped high-doping regions

90 Weakly doped regions

92 Front contacts

94 Back surface field and back contact

96 Antireflection coating

1-22. (canceled)

23. A method for manufacturing a solar cell via a two-stage doping, which comprises the steps of:
forming an oxide layer, which can be penetrated by a first dopant, on at least one part of a surface of a solar cell substrate;
forming an opening in the oxide layer in at least one high-doping region by removing the oxide layer in the high-doping region;
performing a common diffusing step, including:
diffusing the first dopant into the at least one high-doping region of the solar cell substrate through the opening; and
diffusing the first dopant into the solar cell substrate through the oxide layer, wherein the diffusing through openings and through the oxide layer takes place at a same time in the common diffusing step and the solar cell substrate is diffused in the common diffusing step in an at least partially hydrophilic state.

24. The method according to claim 23, which further comprises:
etching the solar cell substrate, after the forming of the oxide layer and before the common diffusing step, in a solution containing an acid which oxidizes metallic impurities;
rinsing the solar cell substrate, after the etching, in deionized water; and
drying the solar cell substrate after the rinsing.

25. The method according to claim 23, which further comprises:
etching the solar cell substrate, after the forming of the oxide layer and before the common diffusing step, in an alkaline etching solution; and
exposing at least one partial region of the oxide layer to the alkaline etching solution without protection, and the at least one unprotected partial region of the oxide layer being left at least in part on the solar cell substrate.

26. The method according to claim 23, which further comprises performing an overetching of the solar cell substrate with a hydrofluoric acid-containing medium between the forming of the oxide layer and the common diffusing step.

27. The method according to claim 25, which further comprises etching the solar cell substrate, in addition to the etching in the alkaline etching solution, in a highly dilute or buffered hydrofluoric acid solution having an oxide etching rate of less than 25 nm per minute.

28. The method according to claim 24, which further comprises reducing a thickness of the oxide layer during the etching step overall by less than 50% of its starting thickness.

29. The method according to claim 23, which further comprises:
providing a silicon substrate as the solar cell substrate; and
providing a silicon oxide layer as the oxide layer.

30. The method according to claim 23, wherein the forming of the oxide layer is formed by one of: by means of a thermal oxidation of the solar cell substrate, by means of a wet thermal oxidation of the solar cell substrate, by means of chemical vapor deposition or applying by means of action of UV light in an ozone atmosphere.

31. The method according to claim 23, wherein before the forming of the oxide layer, forming at least on a part of a surface of the solar cell substrate a microstructure, structures of the microstructure having substantially a structure diameter of less than 100 μm, and at least one part of the oxide layer being subsequently formed on the microstructure.

32. The method according to claim 23, which further comprises forming the oxide layer with a thickness of between 2 nm and 70 nm.

33. The method according to claim 23, which further comprises forming the oxide layer such that its thickness varies by less than ±1 nm.

34. The method according to claim 23, which further comprises:
before the forming of the oxide layer, forming a layer containing a second dopant on a back of the solar cell substrate; and
diffusing the second dopant from the layer into the solar cell substrate.

35. The method according to claim 34, which further comprises removing glass layers formed during the forming of the layer containing the second dopant or during diffusing-in of the second dopant.

36. The method according to claim 34, which further comprises:
during the common diffusing step, diffusing the first dopant into the back of the solar cell substrate;
removing an oxide layer, which may be present on the back, before performing the common diffusing step of the first dopant; and
after diffusing of the first dopant step, applying a silicon nitride layer to a front and the back of the solar cell substrate.

37. The method according to claim 23, which further comprises:
forming the oxide layer on a front and on a back of the solar cell substrate; and
providing the oxide layer formed on the back of the solar cell substrate with a protective layer being resistant to an oxide etching medium.

38. The method according to claim 37, wherein the protective layer applied is a layer made of a material selected from the group consisting of silicon nitride, silicon carbide and aluminum oxide.

39. The method according to claim 37, which comprises:
before performing the common diffusing step, on the back of the solar cell substrate, introducing local openings into the oxide layer and also the protective layer; and
removing the oxide layer on the front by means of an oxide etching medium.

40. The method according to claim 39, which further comprises disposing electrical contacts in the local openings on the back.

41. The method according to claim 23, which further comprises removing glass layers formed during the common diffusing step together with at least one part of the oxide layer.

42. The method according to claim 23, which further comprises forming one of an emitter or a back surface field via the two-stage doping.

43. The method according to claim 24, which further comprises providing a hydrochloric acid as the acid.

44. The method according to claim 25, which further comprises providing an alkali hydroxide solution as the alkaline etching solution.

45. The method according to claim 23, which further comprises:
etching the solar cell substrate, after the forming of the oxide layer and before the common diffusing step, in a highly dilute or buffered hydrofluoric acid solution; and
exposing at least one partial region of the oxide layer to the alkaline etching solution without protection, and the at least one unprotected partial region of the oxide layer being left at least in part on the solar cell substrate.

46. The method according to claim 24, which further comprises reducing a thickness of the oxide layer during the etching step overall by less than 25% of its starting thickness.

47. The method according to claim 29, which further comprises providing a multicrystalline silicon substrate as the silicon substrate.

48. The method according to claim 23, which further comprises forming the oxide layer with a thickness of between 10 nm and 70 nm.

49. The method according to claim 34, which further comprises removing, via wet chemistry, glass layers formed during the forming of the layer containing the second dopant or during diffusing-in of the second dopant.

50. The method according to claim 34, which further comprises performing the step of applying the silicon nitride layer via one of a low-pressure chemical vapor deposition process or an atmospheric pressure chemical vapor deposition process.

51. The method according to claim 38, which comprises:
before performing the common diffusing step, on the back of the solar cell substrate, introducing local openings, by means of laser ablation, into the oxide layer and also the protective layer; and
removing the oxide layer on the front by means of a hydrofluoric acid-containing solution, after the common diffusing step.

52. The method according to claim 39, which further comprises disposing electrical contacts, via screen printing, in the local openings on the back.

53. The method according to claim 23, which further comprises removing glass layers formed during the common diffusing step, using an oxide etching medium, together with at least one part of the oxide layer.

54. The method according to claim 23, wherein before the forming of the oxide layer, forming at least on a part of the surface of the solar cell substrate a microstructure having a wet-chemically formed texture, structures of the microstructure having substantially a structure diameter of less than 50 μm, and at least one part of the oxide layer being subsequently formed on the microstructure.

55. The method according to claim 23, wherein before the forming of the oxide layer, forming at least on a part of the surface of the solar cell substrate a microstructure having a wet-chemically formed texture, structures of the microstructure having substantially a structure diameter of less than 15 μm, and at least one part of the oxide layer being subsequently formed on the microstructure.

56. A solar cell, comprising:
a solar cell substrate having a front and a back;
a two-stage doping disposed on said front and formed using a first dopant;
a doped layer which is formed on said back of said solar cell substrate using a second dopant, the second dopant being of a type opposite to said first dopant, the first dopant diffused into a partial region of said doped layer that faces said back of said solar cell substrate, said first dopant overcompensating said second dopant in said partial region; and
a silicon nitride cover layer disposed at least on said front and said back.

57. A solar cell manufactured using a method according to claim 23.
